(19) United States
(12) Patent Application Publication
(10) Pub. No.: US 2026/0058636 A1
(43) Pub. Date: Feb. 26, 2026

(54) ACTIVE NULLIFICATION OF STRAY CHARGES ON FLOATING ELECTRODES IN MICRO OR NANO ELECTROMECHANICAL RESONATOR SYSTEMS

(71) Applicant: Indian Institute of Science, Kamataka (IN)

(72) Inventors: Disha Chugh, Bengaluru (IN); Saurabh A. Chandorkar, Bengaluru (IN)

(73) Assignee: Indian Institute of Science, Kamataka (IN)

(21) Appl. No.: 19/309,982

(22) Filed: Aug. 26, 2025

(30) Foreign Application Priority Data
Aug. 26, 2024 (IN) 202441064289

(51) Int. Cl. H03H 9/24; B81B 3/00

(52) U.S. Cl. CPC H03H 9/2405; B81B 3/0021; B81B 2201/0271

(57) ABSTRACT

The present disclosure relates to methods and system that enable a real time and active compensation for the effects of accumulated/dissipated stray charges/or accumulated/dissipation stray charges on an electrically floating electrode that couples electrostatically with a resonator by means of application of suitably controlled voltage on another electrode, for e.g., a compensating electrode, that is capacitively coupled with the electrically floating electrode. The control signal for the compensating electrode can be obtained using a feedback circuit that measures the voltage generated by stray charges on the electrically floating electrode using suitable signal conditioning electronics. The present subject matter provides methods to compensate feedthrough signal linking from an input electrode to the output electrode.

### TECHNICAL FIELD

The present disclosure generally relates to Micro Electro-mechanical System (MEMS) or Nano Electro-mechanical System (NEMS) devices. More particularly, the present disclosure relates to methods and systems of compensating for stray charges induced on an electrically floating electrode of Micro Electro-Mechanical (MEM) devices or Nano Electro-Mechanical (NEM) devices.

### BACKGROUND

MEMS devices and NEMS devices offer miniaturized solutions and are generally used in various applications, for example, but not limited to, inertial sensors-such as accelerometers and gyroscopes, microfluidics devices-such as ink-jet printers, mass flow sensors, and bio-chemical analysis devices, optical applications-such as displays and optical switches, pressure measurement devices used in medical, automotive, and industrial fields, Radio-Frequency (RF) devices-including switches, radar components, and RF components integrated in laptop computers and cell-phones, micro-relays, disk-heads, and the like. Trdnsducing and sensing in such devices may be performed using a variety of modes, including, but not limited to, piezoelectric, piezo-resistive, electro-static, electro-thermal, electro-magnetic, and optical methods. The most widely implemented transduction method involves capacitive actuation and sensing. Capacitive transductions offer benefits of cost-effective fabrication, minimal power consumption, low noise, negligible impact on quality factor and low temperature coefficients.

The information disclosed in this background of the disclosure section is only for enhancement of understanding of the general background of the disclosure and should not be taken as acknowledgment or any form of suggestion that this information forms prior art already known to a person skilled in the art.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary presents certain concepts relating to one or more aspects relating to the mechanisms disclosed herein in a simplified form to precede the detailed description presented below.

Regarding the capacitively transduced MEMS devices, when measuring voltage on an electrically-floating electrode, either the drifts due to accumulation and/or dissipation of stray-charges in output voltage while measuring continuously in time, may be taken into account or continuous time measurement has to be eliminated in order to eliminate drift by removing stray charges periodically. The present disclosure provides a real time method to actively compensate accumulated and/or dissipated stray charges on an electrically floating electrode that couples electrostatically/capacitively with a Micro Electro-Mechanical (MEM) or Nano Electro-Mechanical (NEM) resonator system by means of application of suitably controlled voltage on another electrode, for e.g., a compensating electrode, that is capacitively coupled with the electrically-floating electrode. The control signal for the compensating electrode can be obtained using a feedback circuit that measures the voltage generated by stray charges on the electrically-floating electrode and compares this measured voltage against some preset voltage using suitable signal conditioning electronics to generate the said control voltage. The present subject matter also provides methods to compensate feedthrough signal linking from an input electrode to the output electrode, whereby the feedthrough signal bypasses the intermediary MEM resonator system, by suitable application of a scaled input ac voltage on the compensating electrode that is capacitively/electrostatically coupled with the electrically floating electrode from which the output voltage is measured.

Disclosed are micro or nano electromechanical resonator systems and methods of compensating for stray charges induced on an electrically floating electrode of MEM resonator system or NEM resonator system.

In one illustrative example, a capacitively transduced Micro or Nano Electro-mechanical resonator system is provided. The capacitively transduced Micro or Nano Electro-mechanical-resonator system comprises an actuating unit, a resonance unit, a sensing unit, and an adaptive tuning unit. The actuating unit is configured to generate an actuating signal based on an input signal. The resonance unit is coupled to the actuating unit, and configured to resonate in response to the actuating signal based on a value of capacitance associated with the resonance unit. The sensing unit is capacitively coupled to the resonance unit, the sensing unit configured to, in response to one or more of generation and resonation of the actuating signal, sense a capacitance component, associated with the sensing unit, related to stray charges on the sensing unit. The adaptive tuning unit is coupled to the sensing unit, to generate an offset signal to compensate an effect of the capacitance component on the sensing unit.

In another example, a method of compensating for stray charges induced on an electrically floating electrode of MEM resonator systems or NEM resonator systems is provided. The method comprises generating, by an actuating unit, an actuating signal based on an input signal. The method further comprises resonating a resonance unit coupled to the actuating unit, in response to the actuating signal based on a value of capacitance associated with the resonance unit. Further, the method comprises, in response to one or more of generation and resonation of the actuating signal, sensing, by a sensing unit capacitively coupled to the resonance unit, a capacitance component, associated with the sensing unit, related to stray charges on the sensing unit. The method further comprises generating, by an adaptive tuning unit coupled to the sensing unit, an offset signal to compensate an effect of the capacitance component on the sensing unit.

Other advantages associated with the aspects disclosed herein will be apparent to those skilled in the art based on the accompanying drawings and detailed description.

### BRIEF DESCRIPTION OF THE DRAWINGS

The embodiments of the disclosure itself, as well as a preferred mode of use, further objectives, and advantages thereof, will best be understood by reference to the following detailed description of an illustrative embodiment when read in conjunction with the accompanying drawings. One or more embodiments are now described, by way of example only, with reference to the accompanying drawings in which:

FIG. 1 illustrates a classification diagram of existing capacitive readout methods for MEM resonator systems;

FIGS. 2a-2c illustrate schematic diagrams of Double Ended Tuning Fork (DETF) resonator used by the present subject matter, in accordance with an embodiment of the present disclosure;

FIG. 3 illustrates a block diagram of a capacitively transduced Micro or Nano Electro-mechanical resonator system, in accordance with an embodiment of the present disclosure;

FIG. 4 illustrates a schematic diagram of a capacitive MEM resonator system, in accordance with an embodiment of the present disclosure;

FIG. 5a illustrates circuit schematic of a capacitive MEM resonator system for floating voltage sensing, in accordance with some embodiments of the present disclosure;

FIG. 5b illustrates circuit schematic for actively compensating for stray charges which appear on the electrically floating sense electrode for the case when the device is pre-characterized, in accordance with some embodiments of the present disclosure;

FIG. 5c illustrates circuit schematic for actively compensating for stray charges which appear on the electrically floating sense electrode for the case when the device is not pre-characterized, in accordance with some embodiments of the present disclosure;

FIG. 6a illustrates schematic representations for a DETF resonator for actively compensating stray charges which appear on the electrically floating sense electrode a spring-mass-damper equivalent of the DETF resonator for the first two in-plane resonant modes, in accordance with some embodiments of the present disclosure;

FIG. 6b illustrates electrical circuit equivalent of the resonator system with the VA used, when transducing and sensing capacitance are kept as variable capacitances, in accordance with some embodiments of the present disclosure;

FIG. 7a illustrates a connection schematic of resonance measurement system, and FIG. 7b illustrates an active measurement setup that demonstrates the characterization of the first two in-plane resonance modes, in accordance with some embodiments of the present disclosure; and

FIG. 8 illustrates a flowchart of a method for compensating for stray charges induced on an electrically floating electrode of Micro Electro-mechanical (MEM) resonator systems or Nano Electro-mechanical (NEM) resonator systems, in accordance with some embodiments of the present disclosure an aspect of the subject matter in accordance with one embodiment.

The figures depict embodiments of the disclosure for purposes of illustration only. One skilled in the art will readily recognize from the following description that alternative embodiments of the structures and methods illustrated herein may be employed without departing from the principles of the disclosure described herein.

### DESCRIPTION OF THE DISCLOSURE

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood, however that it is not intended to limit the disclosure to the particular forms disclosed, but on the contrary, the disclosure is to cover all modifications, equivalents, and alternative falling within the spirit and the scope of the disclosure.

The terms “comprises”, “comprising”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a device or system or apparatus proceeded by “comprises . . . a” does not, without more constraints, preclude the existence of other elements or additional elements in the device or system or apparatus.

In the following detailed description of the embodiments of the disclosure, reference is made to the accompanying drawings that form a part hereof, and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

State of the art capacitive MEMS devices, involving capacitive actuation and sensing, may include an electrically floating electrode and, during operation, stray charges may be induced on the electrically-floating electrode. Generally, the capacitive MEMS devices lack a means of compensating for the stray charges induced on the electrically-floating electrode while keeping the intended electrically-floating electrode electrically floating in continuous time mode of operation. Therefore, capacitive MEMS devices, which use electrically-floating electrodes as a part of the system operation, suffer from detrimental effects of the stray charges. Although, the existing state of the art are mentioned with respect to the MEMS devices, similar detrimental effects of the stray charges are faced by the NEMS devices.

To solve the problem of stray charges and other problems related to stray charges which accumulate on and/or dissipate from the electrically-floating electrode of the MEMS devices, the present subject matter provides methods and systems for active nullification of stray charges on the electrically-floating electrode in MEMS devices, such as MEM or NEM resonator system. The present subject matter provides techniques to add an additional field via a secondary electrode (or the compensating electrode) placed in vicinity of the electrically-floating electrode in the MEMS devices and/or MEM resonator systems (also referred hereinafter as capacitively transduced or capacitive MEMS devices and/or capacitively transduced or capacitive MEM resonator systems). The applied voltage on the secondary electrode controls the voltage of the electrically-floating electrode. Further, by measuring the low frequency parameters of voltage measured on the electrically-floating electrode, which corresponds to slow varying accumulation/dissipation of stray-charges, a feedback signal is generated which is applied on a secondary/tuning/compensating electrode to negate the effect of the stray charges or the stray charge itself in real time. The feedback signal can be generated cither purely through analog-electronics or via a microcontroller and/or a Digital to Analog converter.

The techniques provided by the present subject matter allows enabling of voltage-sensing on an electrically-floating electrode or a floating electrical node using bias-tuning/compensating/secondary electrodes in a capacitively transduced MEM resonator system since the stray charge accumulating on/dissipating from such a node can be compensated in real time. The present disclosure is not only restricted to MEMS devices and can also be applied to similar devices experiencing similar issues in the field of the invention. In some embodiments, the present disclosure is applicable on Nanoelectromechanical systems (NEMS) devices as well.

The methods and systems of the present disclosure solve a technical problem for compensating stray charges and/or capacitance on the electrically-floating electrode of the MEMS devices and/or resonator systems by implementing active nullification of the stray charges. The present disclosure solves this technical problem as described in below embodiments.

The solution provided by the present subject matter also forms a basis to compensate for other inherent problems of low bandwidth (BW), reduction in noise, generally suffered by transimpedance amplifiers (TIAs)-based solutions and switched capacitance-based solutions.

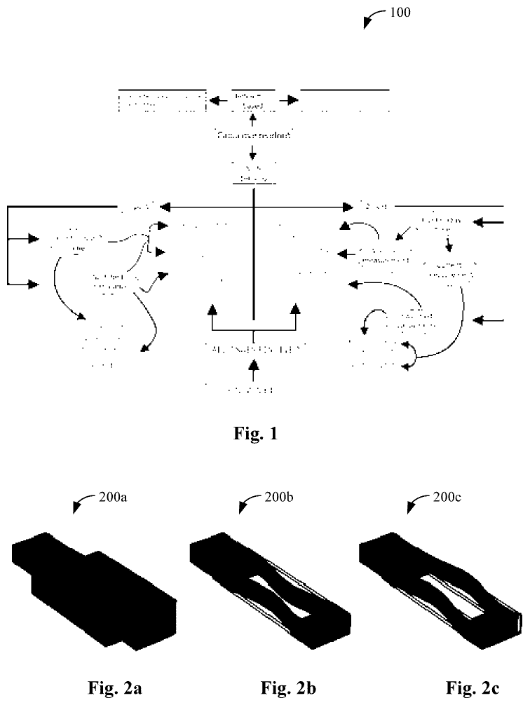

FIG. 1 illustrates a classification diagram 100 of existing capacitive readout methods for MEMS devices. As illustrated in FIG. 1, capacitive sensing can be carried out in self-sensing mode or with a reference device. In reference sensing, which uses the reference device, a non-actuated reference device provides a fixed reference capacitance to detect changes in capacitance in the transducing device. While this approach helps reduce the effect of the parasitic capacitance, this implementation requires fabrication of a similar dummy device alongside the actual resonator, occupying valuable space of the MEMS device. On the other hand, in the self-sensing mode, both actuation and sensing are performed on the transduced resonator itself without incorporating an external dummy device. Further, in the self-sensing mode, differential sense and drive scheme can be used to diminish the effects of parasitic capacitance without sacrificing precious real estate on a wafer of the MEMS device.

In the self-sensing devices, capacitive measurement can be performed in one-port or two-port configurations. For both the one-port or two-port configurations, capacitive measurements can be classified into continuous-time or switched-mode categories. In the one-port configuration, sensing is done on the same electrode as the one on which the actuation signal is applied. For one-port measurement configuration, the sensed signal can be either voltage or current and it complements the actuation signal. The main drawbacks associated with the one-port or two-port are that the feedthrough capacitance is high and the device is deformed in its resting position which causes early onset of nonlinear behaviour associated with the device. One the other hand, the two-port configuration utilizes separate sense and actuation electrodes. In the two-port configuration, regardless of what the actuation signal is, sensed signal can be a current, charge, or voltage signal. Voltage sensing configurations, such as opposite excitation sensing, typically employ a capacitive half bridge circuit driven by two out of phase Alternating Current (AC) sources to enable ideal differential sensing. Further, the change in capacitance is measured by demodulating the amplified output voltage of the half-bridge circuit, either through source-frequency locking or through frequency-mixing followed by a low-pass filter. A major drawback of the two-port configuration is that the resonator needs to be left electrically floating, which makes it susceptible to stray charge accumulation. To address the problem of stray charge accumulation, the most commonly employed solution is to use switched capacitor circuits. Nevertheless, added circuit increases operational complexity as well as noise in the circuit of the device. Furthermore, when the switched capacitor is draining the charges from the floating node, sensing cannot be performed, thereby, preventing the device to operate in a continuous time mode of operation.

Another way to configure capacitive sensing is by applying a Direct Current (DC) bias to the moveable electrode/resonator. The displacement current arising at the sense electrode due to capacitance change occurring as a result of resonator's motion is measured using an integrator circuit. However, this method also suffers from the same shortcomings of stray charge accumulation on the sense electrode just like the earlier mentioned case of voltage sensing configuration. To address the issue of robust DC biasing at the sense electrode and still having an electrically floating electrode in the system, a solution has been proposed to use separate actuation and sensing comb structures while leaving the rotor at an electrically floating potential. Wherein, two out of phase AC signals are applied to the actuation comb structure, and the sense comb is terminated in two transimpedance amplifiers (TIAs) enabling differential sensing. The parametric excitation achieved by using this configuration is resistant to the influence of the stray charge that might accumulate and/or dissipate on the electrically-floating resonator. However, this method is inapplicable for cases where parametric excitation is not sought after and requires rather large input voltages to generate measurable signals.

Another existing technique uses electrically floating resonator with desired charge embedded on it to eliminate the need for DC power source connected to the resonator. However, in such technique, such a resonator suffers from the issues of charge leakage and requires frequent charge replenishment. To overcome this issue of charge leakage, yet another existing technique is proposed which implements fabricating encapsulated MEMS devices using techniques like the epi-seal process. The devices fabricated in epi-seal process show extremely stable charge storage capability. However, even after the charge dissipation is mitigated, the stray charge problem persists and needs to be addressed. It is important to note that while the above existing techniques keep their moving electrode/resonator at electrically floating potential, the measurements are conducted by the TIA circuits.

Thus far, TIA has become the de-facto choice for the measurement circuit for the existing resonant applications. Following reasons explain how TIA mitigates the above-mentioned challenges encountered in voltage-measurement techniques. Firstly, TIA provides robust DC virtual ground to the sense electrode/target electrode. Secondly, TIA provides a definite potential to the sense electrode by being conductively connected in the circuit, making it immune to random charges reaching the sense electrode. Thirdly, TIA avoids loading of the resonator, as potential at the sense electrode is significantly diminished by the high open-loop gain, A_{OL}, of the op-amp used in the TIA stage. Using the TIA configuration in an oscillator with a capacitively sensed resonator has been suggested to have the benefit of using fewer electronic components. This is because only a 180-degree phase correction stage is needed after the resonator/TIA, resulting in less noise being introduced to the entire system, which includes the resonator and amplifier.

However, the TIA based measurement largely suffers from gain and noise performance issues when used with MEMS devices. Further, TIA built using commercially available op-amps suffers from an inherent limitation in achieving high gain and bandwidth (BW) simultaneously. To achieve good signal-to-noise ratio performance and higher stability, a TIA needs to have a higher gain. However, this directly conflicts with the need for a higher bandwidth.

As dictated by the constant gain-bandwidth product of an op-amp, if a higher 3 dB bandwidth is to be achieved, the gain requirement from the amplifier needs to be reduced.

One or more technical problems solved by the present disclosure are explained in detail below.

In the present disclosure, techniques are proposed to overcome the issue of high bandwidth conflict seen in TIA topologies using an electrically-floating sense electrode topology whose voltage is measured using a voltage amplifier. Furthermore, the DC potential of the sense electrode (also referred hereinafter and in figures as sensing electrode) can be independently controlled using a gate/compensating/secondary electrode. Therefore, the present subject matter allows overcoming the issue of robust DC biasing faced in continuous-time voltage measurement, while maintaining the sense electrode at an electrically floating potential. The present disclosure introduces an exemplary circuit model that accounts for all the parasitic capacitors as well as the effect/issues associated with the gate/compensating/secondary electrode. For some embodiment, the present disclosure considers Epi-seal encapsulated Double Ended Tuning Fork (DETF) device. In some embodiments, an output voltage response as well as input referred noise for a DETF is derived for given DC bias voltage, ac drive voltage, and gate/compensating/secondary voltage for a non-inverting voltage amplifier (NIVA) configuration.

The present subject matter showcases and provides various advantages, including i) the gate/compensating/secondary voltage tunes the sense electrode voltage to desired value in NIVA configuration and should work for any amplifier configuration which keeps the sense electrode at electrically floating potential ii) the NIVA configuration is more tolerant to high parasitic line capacitance as compared to TIA which becomes unstable iii) the input referred noise is superior for NIVA configuration compared to TIA iv) a higher bandwidth is achievable in the NIVA configuration for a given OPAMP vi) No resonator characteristic measurements are affected by switching to NIVA configuration when switching from a TIA configuration. Therefore, the present subject matter deals with the shortcomings associated with the standard two-port voltage measurement.

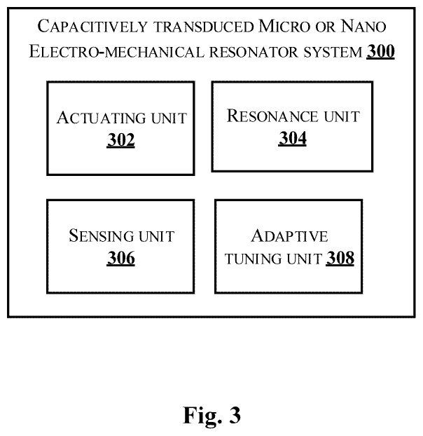

FIGS. 2a-2c illustrate schematic diagrams of Double Ended Tuning Fork (DETF) resonator used by the present subject matter, in accordance with an embodiment of the present disclosure. FIG. 2a illustrates schematic diagram 200a of DETF resonator used as an exemplary implementation of the present subject matter. FIG. 2b illustrates a schematic diagram 200b showing a first in-plane resonant mode of the DETF resonator used as an exemplary implementation of the present subject matter. FIG. 2c illustrates schematic diagram 200c showing a second in-plane resonant mode of the DETF resonator used as an exemplary implementation of the present subject matter. In the subsequent sections, a voltage response is developed at the sense electrode for the VA-model based sensing methodologies. The present disclosure describes the exemplary embodiments with respect to a split-electrode DETF. However, a person skilled in the art will appreciate that similar, analogous, and/or equivalent techniques may also be implemented using any of the capacitively-transduced micro- and nano-mechanical resonator systems (also referred hereinafter and in the figures as resonator system).

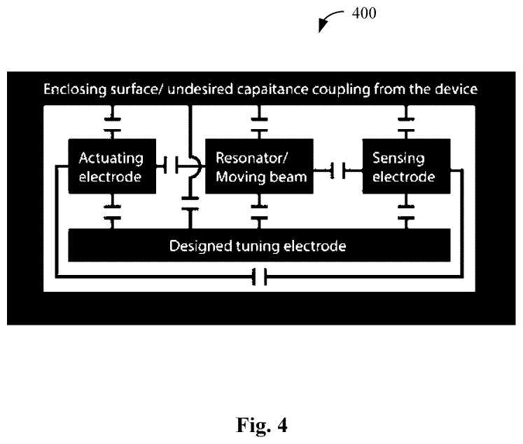

FIG. 3 illustrates a block diagram of a capacitively transduced Micro or Nano Electro-mechanical resonator system 300, in accordance with some embodiments of the present disclosure. The capacitively transduced Micro or Nano Electro-mechanical resonator system 300 (also referred hereinafter as a resonator system 300 for the sake of brevity) comprises an actuating unit 302, a resonance unit 304, a sensing unit 306, and an adaptive tuning unit 308.

The actuating unit 302 may be configured to generate an actuating signal based on an input signal. In an example, the actuating unit 302 may generate the actuating signal for providing an input stimulus that may initiate mechanical vibrations in the resonator structure. Such vibrations are crucial for the resonator system 300 to perform associated sensing or timing functions. For example, the actuating signal may excite the resonator system 300 into associated fundamental or desired vibrational mode. Such excitation may help in maintaining a stable oscillations at a resonant frequency of the resonator system 300. Therefore, such excitations may enable conversion of physical parameters into measurable frequency shifts. For example, the physical parameters may include, without limitation, pressure, acceleration, and/or temperature. The resonance unit 304 is coupled to the actuating unit 302. The resonance unit 304 may be configured to resonate in response to the actuating signal based on a value of capacitance associated with the resonance unit 304.

The sensing unit 306 may be capacitively coupled to the resonance unit 304. The sensing unit 306 may be configured to sense a capacitance component, associated with the sensing unit 306, in response to one or more of generation and resonation of the actuating signal. In an embodiment, the capacitance component may be related to stray charges on the sensing unit 306.

In an embodiment, the sensing unit 306 may be coupled to a Direct Current (DC) bias voltage generation unit (not shown). The DC bias voltage generation unit may be configured to generate a DC bias voltage. The DC bias voltage may be transferred to the adaptive tuning unit 308. In an example, the adaptive tuning unit 308 may be configured to generate the offset signal based on the DC bias voltage. The offset signal may be generated to compensate the effect of the capacitance component on the sensing unit 306.

In an embodiment, the sensing unit 306 may be coupled to an Alternating Current (AC) bias voltage generation unit. The AC bias voltage generation unit may be configured to generate an AC bias voltage. The AC bias voltage may be transferred to the adaptive tuning unit 308. In an embodiment, the adaptive tuning unit 308 may be configured to generate the offset signal based on the AC bias voltage. The offset signal may be generated to compensate the effect of the capacitance component on the sensing unit 306.

In an embodiment, the sensing unit 306 may be further configured to sense the resonation of the resonance unit 304. In an exemplary embodiment, the capacitance component may further relate to resultant charges associated with the one or more of generation and resonation of the actuating signal. For example, the capacitance component may be a component related to one of a parasitic capacitance, an intended capacitance, or a stray capacitance. For example, the intended capacitance may be a target or design-dependent capacitance related to the resonator system.

The adaptive tuning unit 308 is coupled to the sensing unit 306. The adaptive tuning unit 308 is configured to generate an offset signal to compensate an effect of the capacitance component on the sensing unit 306. In an exemplary embodiment, to compensate an effect of the capacitance component on the sensing unit 306, the adaptive tuning unit 308 may be configured to independently control a Direct Current (DC) component associated with the sensing unit 306. In an example, by independently controlling the DC component, the sensing unit 306 may be maintained at an electrically floating potential. In an example, the sensing amplifier may be a differential amplifier. The adaptive tuning unit 308 may include a feed-through compensating unit.

In an embodiment, the adaptive tuning unit 308 may include an external AC power source configured to provide a power value set to cancel the feed-through noise due to the parasitic capacitance.

In an embodiment, the resonator system 300 comprises a sensing amplifier (not shown in FIG. 3) and a Low Pass Filter (LPF) (not shown in FIG. 3). For example, the sensing amplifier may be coupled to the sensing unit 306. The sensing amplifier may be configured to amplify an output signal received from the sensing unit 306. In some embodiments, the Low Pass Filter (LPF) may be coupled to the sensing amplifier. The LPF may be configured to attenuate high-frequency noise components above a predetermined cutoff frequency, from the amplified output signal received from the sensing amplifier. The resonator system 300 may further include a signal processing element (not shown in FIG. 3). The signal processing element may be coupled to the LPF. The signal processing element may be configured to process a filtered signal received from the LPF. Further, the signal processing element may be configured to transfer the processed signal to the adaptive tuning unit 308. In an example, the adaptive tuning unit 308 may be configured to generate the offset signal based on the processed signal, to compensate the effect of the capacitance component on the sensing unit 306.

In an embodiment, the signal processing element may be further configured to receive an input signal comprising the filtered signal, received from the LPF, and a reference voltage. The signal processing element may be further configured to process the input signal and transfer the processed input signal to the adaptive tuning unit 308. The adaptive tuning unit 308 may be configured to generate the offset signal based on the processed input signal, to compensate the effect of the capacitance component on the sensing unit 306.

In an embodiment, the resonator system 300 comprises an enclosure (not shown in FIG. 1) for enclosing at least one of the actuating unit 302, the resonance unit 304, the sensing unit 306, and the adaptive tuning unit 308. The enclosure may prevent intrusion of external and/or additional stray charges from surrounding of the resonator system 300.

A person skilled in the art will appreciate that the present disclosure is applicable to any type of suitable Micro or Nano Electro-mechanical resonator system other than the above-mentioned resonator system.

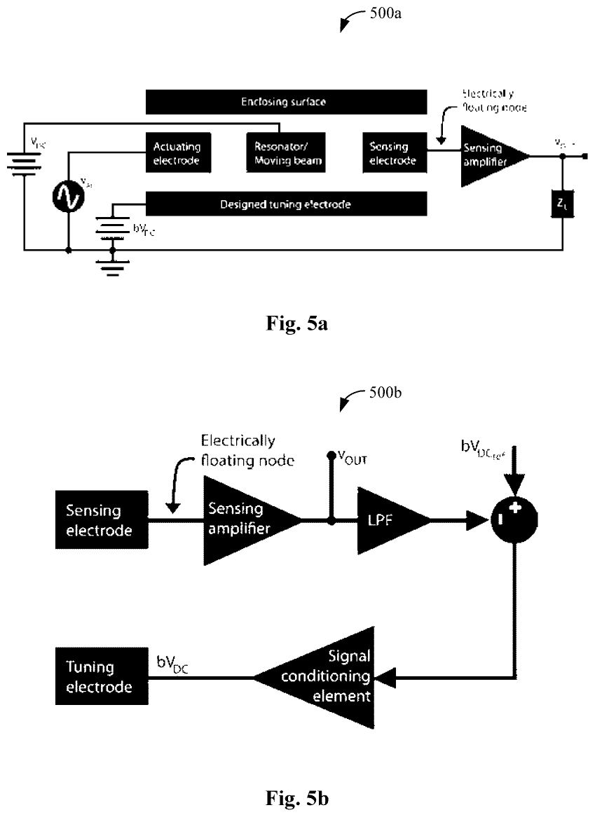

FIG. 4 illustrates a schematic diagram 400 of a capacitively transduced MEM resonator system, in accordance with an embodiment of the present disclosure. In an embodiment, the capacitively transduced MEM resonator system is a capacitive air/vacuum/dielectric-gap-closing MEMS resonator system. The capacitively transduced MEM resonator system may also be referred hereinafter, in the present disclosure, as a MEMS resonator system or a MEMS device. As illustrated in FIG. 4, the capacitive air/vacuum/dielectric-gap-closing MEMS resonator system includes an actuation electrode (also referred hereinafter and in figures as actuating electrode), a resonator or a moving beam, a sense electrode, a designed tuning electrode, and an enclosing surface, this enclosing surface can be composed of same or different material at different spatial positions around the resonator system. The enclosing surface may contribute undesired capacitances coupling to the MEMS device. The MEMS device may implement voltage-sensing on electrically-floating electrical node, such as resonator, using bias-tuning/compensating/gate/secondary electrodes. By using the illustrated configuration, the exemplary MEMS device can actively compensate, in real-time, for accumulated stray charges on an electrically floating electrode that couples electrostatically with the MEMS resonator system and the unknown/time varying stray capacitances, by means of application of suitably controlled voltage on another electrode(s), such as the gate/tuning/compensating/secondary electrode, that is capacitively coupled with the electrically-floating electrode. The control signal for the gate/tuning/compensating/secondary electrode can be obtained using a feedback circuit as illustrated in FIG. 4, that measures and compensates the voltage generated by stray charges on the electrically-floating electrode using suitable signal conditioning electronics.

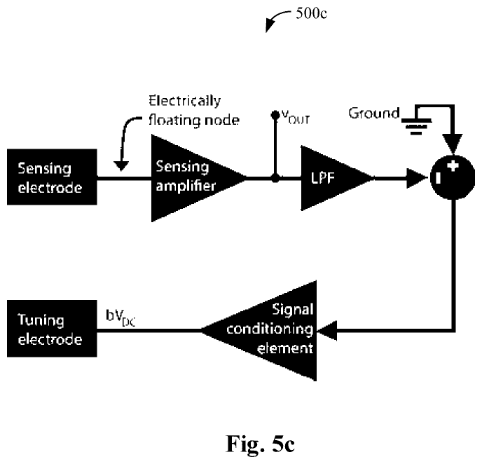

FIGS. 5a-5c illustrate circuit schematics of different circuits of the capacitively transduced MEM resonator system. FIG. 5a illustrates circuit schematic 500a of a capacitively transduced MEM resonator system for floating voltage sensing, in accordance with some embodiments of the present disclosure. As illustrated in FIG. 5a, a required DC biasing voltage using a control knob bV_{DC} is modulated to actively compensate for the effects of the stray charges (or the stray charge itself) which appear on the electrically floating sense electrode. Further details for the tuning/compensating DC biasing voltage are provided in the below description with respect to other Figures. FIG. 5b illustrates circuit schematic 500b for actively compensating for stray charges which appear on the electrically floating sense electrode for the case when the capacitively transduced MEM resonator system is pre-characterized, in accordance with some embodiments of the present disclosure. As illustrated in FIG. 5b, bV_{DC_ref} is the reference voltage known from the pre-characterization. The circuit schematic of FIG. 5b includes sense electrode, which is an electrically floating node, a sensing amplifier, a Low Pass Filter (LPF), a signal conditioning element, and a tuning electrode. In operation, bV_{DC_ref} may be added to the output of the LPF which is inputted with the output of the sensing amplifier. Further, the added output of bV_{DC_ref} and output of LPF may be inputted to the signal conditioning element which may, in turn condition the received signal. Further, the signal conditioning element may forward the conditioned signal to the tuning/gate/compensating/secondary electrode for tuning the floating node in order to nullify the effects of stray charges (or the stray charge itself)/stray capacitance. FIG. 5c illustrates circuit schematic 500c for actively compensating for the effects of stray charges (or the stray charge itself) which appear on the electrically floating sense electrode for the case when the capacitively transduced MEM resonator system is not pre-characterized, in accordance with some embodiments of the present disclosure.

In some embodiments, the below equation 1 is provided for floating voltage in case of generic MEMS resonator system shown in FIGS. 5a-5c.

$${V}_{sensing} = {\underbrace{\frac{{C}_{transducing} \frac{{x}_{resonator}}{{g}_{nominal}} {V}_{DC}}{{C}_{total \_ with \_ amplifier}}}}_{{T}_{rd}} + {\underbrace{\frac{{C}_{f} {v}_{ac}}{{C}_{total \_ with \_ amplifier}}}}_{{F}_{th}} + {\underbrace{\frac{[ {C}_{transducing} + b ( {C}_{enclosing \_ sensing} ) ] ( {V}_{DC} )}{{C}_{total \_ with \_ amplifier}}}}_{dc component} \qquad Equation 1$$

Further, in view of equation 1, to have 0V dc potential on the electrically floating sense electrode DC component is equated with the value of b indicated in the below equation 2:

$$b = \frac{- {C}_{transducing}}{{C}_{enclosing \_ sensing}} \qquad Equation 2$$

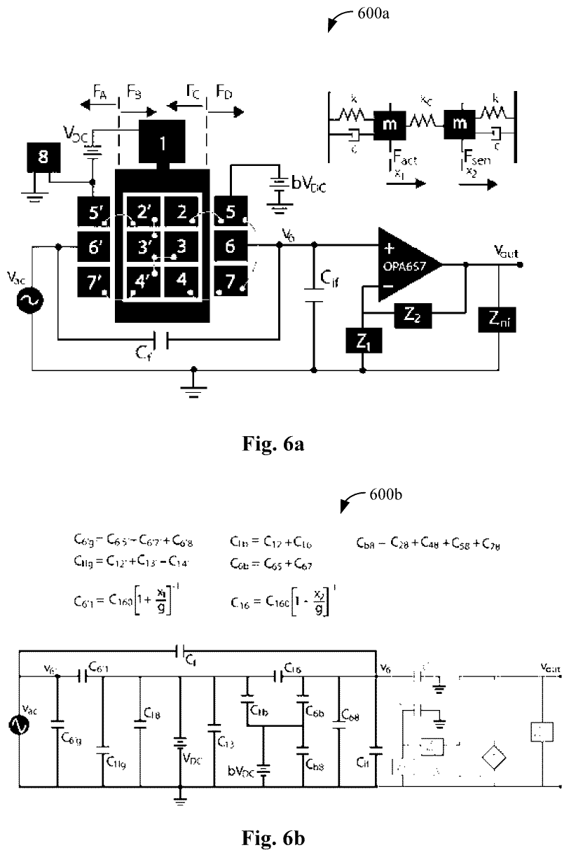

FIG. 6a illustrates circuit schematic representation 600a for a DETF resonator and its equivalent spring-mass system for actively compensating for the effect of stray charge (or the stray charge itselfs which appear on the electrically floating sense electrode, in accordance with some embodiments of the present disclosure. As illustrated in FIG. 6a, a Voltage Amplifier (VA)-based sensing system/model for a capacitively transduced MEM resonator system is illustrated, in which the coupled spring-mass system equivalent of the DETF resonator, for the first two in-plane resonant modes, and the circuit schematic used is showcased when sensed using voltage amplifier (VA). As per FIG. 6a, DC forces on both sides of both the DETF arms should balance for linear operation. Further, electrode 8 is the seal and the substrate layer. As illustrated in FIG. 6a, the DETF resonator includes various electrodes.

In FIG. 6a, the electrical connections in VA measurement configuration are illustrated along with the various forces acting on the resonant beams and an equivalent coupled spring mass damper model, for the first two in-plane resonant modes. In the VA measurement configuration, the output electrode 6 of the resonator is kept electrically floating, and the resultant potential is measured using a non-inverting VA configuration.

In some embodiments, the actuation is carried out using electrode 6′. Since air/vacuum/dielectric gap closing capacitive resonators are non-linear systems, to have considerable voltage response at the input frequency compared to the response at harmonic frequencies, a DC voltage source, V_{DC}, is applied to the electrode 1 of the resonator. In addition, linearity of such gap-closing resonators can be improved by maintaining the resonant beams unbent when the applied ac signal, Vac, is 0V. Hence, electrode 3′ is connected to the ground potential to have balanced DC electrostatic forces, F_{A}=F_{B}, on the actuation arm of the resonator. Moreover, if DC electro-static forces on actuation and sensed arms are different, F_{A}=F_{B}+F_{C}=F_{D}, it introduces further non-linearity in the system. To minimize non-linearity arising from asymmetric operation of the two beams of a DETF, DC potentials on electrode 3 is pulled to 0V conductively and DC potential on electrode 6 is tuned to 0V using the present subject matter. Since potential on electrode 6 is determined by the electric potentials on the capacitances surrounding this electrode, a control knob bV_{DC} is created on the electrodes 5 & 6 to adjust the DC potential on electrode 6 to 0V as the resonator potential is varied for a given set of coaxial cables and connectors connecting the sense electrode and the input terminal of the amplifier. Active tuning of this bV_{DC} potential can also account for stray charges that might accumulate on the electrically floating electrode due to unaccounted time-varying stray capacitances in the system. To maintain DC force balance on the sensed arm electrodes 2 & 4 are also supplied the bV_{DC} potential. Amongst remaining electrodes, 2′, 4′, 5′, 7′ are connected to the ground potential and electrode 8 can be connected either to bV_{DC} or to the ground potential to avoid detrimental effects of any electrically floating potentials in the device. In an embodiment, electrode 8 may be connected to the ground potential as shown in following section.

However, connecting the resonator system's sense electrode to the input of an amplifier poses the potential problem of having a conductive path from the ground terminal to the sense electrode via amplifier's feedback network. Hence, in some embodiments, terminating the resonator into an amplifier for further processing necessitates the input impedance of the amplifier to be purely capacitive, in order to maintain the floating electrical potential on the sense electrode. One such configuration which can be implemented using commercially available op-amps is that of a non-inverting VA, as illustrated in FIG. 6a.

FIG. 6b illustrates electrical circuit equivalent 600b of the resonator system with the VA used, when transduced and sensed capacitances are kept as variable capacitances, in accordance with some embodiments of the present disclosure. As per FIG. 6b, equivalent circuit schematic of resonator system along with VA system depicts electrically floating sense electrode when resonator is terminated in shown VA configuration. As shown in FIG. 6b, on connecting the sense electrode to the input of the amplifier, sense electrode is rendered electrically floating in a complex capacitive network. Voltage signal at the input terminal of the amplifier can be calculated by setting total charge q₆ on electrode 6 to zero and proceeding with calculation detailed in the following equation 3, as presented below

$${v}_{6} = {\underbrace{\frac{{C}_{160} \frac{{x}_{2}}{g} {V}_{DC}}{{C}_{totalVA}}}}_{{T}_{rd}} + {\underbrace{\frac{{C}_{f} {v}_{ac}}{{C}_{totalVA}}}}_{{F}_{th}} + {\underbrace{\frac{[ {C}_{160} + b ( {C}_{65} + {C}_{67} + {C}_{68} ) ( {V}_{DC} ) ]}{{C}_{totalVA}}}}_{dc component} \qquad Equation 3$$

$${C}_{totalVA} = {C}_{16} + {C}_{f} + {C}_{65} + {C}_{67} + {C}_{68} + {C}_{if} + {C}_{+} \approx {C}_{160} + {C}_{f} + {C}_{65} + {C}_{67} + {C}_{68} + {C}_{if} + {C}_{+}$$

The above equation 3 is related to voltage at electrically floating electrode for the system shown in FIG. 6a.

Further, the below equation 4 indicates that, to have 0V dc potential on the electrically floating sense electrode the value of b is:

$$b = \frac{- {C}_{160}}{{C}_{65} + {C}_{67} + {C}_{68}} \qquad Equation 4$$

With respect to equations 3 and 4, C₁₆₀ is the nominal capacitance between electrodes 1 and 6 when the displacement of the resonator is 0 μm, C_{totalVA} is the total capacitance connected/linking to electrode 6, C_{f} is the feedthrough capacitance between the output electrode 6 and the input-signal/actuation electrode 6′, and capacitance between electrodes m and n is denoted by Cₘₙ. Here, the electromechanically transduced signal, T_{rd}, senses displacement, x₂, of the resonator, as opposed to velocity that is measured by standard TIA topology. In the VA configuration, the feedthrough signal, Fₜₕ, does not have a frequency dependence and is solely dependent on the ratio of the feedthrough capacitance C_{f} and C_{totalVA}. Therefore, the measured feedthrough signal stays constant up to 3 dB BW of the VA.

In an embodiment, both T_{rd} and dc component depend on ratio of C₁₆₀ and C_{totalVA}, which is the ratio of nominal capacitance between the electrodes 1 and 6 to sum of various capacitances linking the sense electrode. Ratio of capacitances C₁₆₀ to (C₆₅+C₆₇+C₆₈) determines how much tuning voltage bV_{DC} has to be applied in order to achieve 0V dc voltage on the sense electrode. Since C₆₈>>C₁₆₀ the value of bV_{DC} which results in 0V dc potential at the sense electrode is approximately 0V for applied resonator voltages. Displacement x₂, for the first two in-plane resonant modes of the sensed arm can be calculated by modelling DETF resonator as coupled spring-mass system as solved in below embodiments. For other resonant modes, DETF should be appropriately modelled.

Since the sense electrode is kept electrically floating and the device is epi-sealed, it is assumed that the total charge on this electrode is zero, once it is discharged to ground potential before the operation. Electrical potential on this electrode is deterministic because the device is epi-sealed and can be determined from the following equations 5-8, respectively:

$${q}_{6} = ( {C}_{16} ) ( {v}_{6} - {V}_{DC} ) + ( {C}_{65} + {C}_{67} + {C}_{68} ) ( {v}_{6} - {b V}_{DC} ) + ( {C}_{if} + {C}_{+} ) ( {v}_{6} ) + ( {C}_{f} ) ( {v}_{6} - {v}_{ac} ) = {q}_{0} + Δ q \qquad Equation 5$$

$${v}_{6} = {\underbrace{\frac{{q}_{0} + Δ q}{{C}_{160} + {C}_{65} + {C}_{67} + {C}_{68} + {C}_{if} + {C}_{+} + {C}_{f}}}}_{stray charge component} + {\underbrace{\frac{{C}_{160} ( \frac{{x}_{2}}{g} ) {V}_{DC} + {C}_{f} {v}_{ac}}{{C}_{160} + {C}_{65} + {C}_{67} + {C}_{68} + {C}_{if} + {C}_{+} + {C}_{f}}}}_{ac component} + {\underbrace{\frac{[ {C}_{160} + b ( {C}_{65} + {C}_{67} + {C}_{68} ) ( {V}_{DC} ) ]}{{C}_{160} + {C}_{65} + {C}_{67} + {C}_{68} + {C}_{if} + {C}_{+} + {C}_{f}}}}_{dc voltage = 0 , because enclosing area is too large} \qquad Equation 6$$

$${q}_{6} = ( {C}_{16} ) ( {v}_{6} - {V}_{DC} ) + ( {C}_{65} + {C}_{67} + {C}_{68} ) ( {v}_{6} - {b V}_{DC} ) + ( {C}_{if} + {C}_{+} ) ( {v}_{6} ) + ( {C}_{f} ) ( {v}_{6} - {v}_{ac} ) = 0 \qquad Equation 7$$

$${v}_{6} = {\underbrace{\frac{{C}_{160} ( \frac{{x}_{2}}{g} ) {V}_{DC} + {C}_{f} {v}_{ac}}{{C}_{160} + {C}_{65} + {C}_{67} + {C}_{68} + {C}_{if} + {C}_{+} + {C}_{f}}}}_{ac component} + {\underbrace{\frac{[ {C}_{160} + b ( {C}_{65} + {C}_{67} + {C}_{68} ) ( {V}_{DC} ) ]}{{C}_{160} + {C}_{65} + {C}_{67} + {C}_{68} + {C}_{if} + {C}_{+} + {C}_{f}}}}_{dc voltage = 0 , because enclosing area is too large} \qquad Equation 8$$

In some embodiment, sense electrode voltage has both AC and DC components, however making bV_{DC} 0V by terminating electrodes 5, 7, & 8 in the ground terminal ensures DC voltage appearing on the sense electrode is practically 0V. This is because the combined area of sense electrode facing these three electrodes is significantly large compared to that facing the resonator.

Following equation 9 shows the breakdown of the ac signal because of the feedthrough path between the actuation and the sense electrode, and the transduced signal component. For VA-based measurement voltage signal appearing at the sense electrode is a measure of displacement of the resonator.

$${v}_{6} = {\underbrace{\frac{{C}_{160} ( \frac{{x}_{2}}{g} ) {V}_{DC}}{{C}_{160} + {C}_{65} + {C}_{67} + {C}_{68} + {C}_{if} + {C}_{+} + {C}_{f}}}}_{\begin{matrix}transduced signal depends on the arm \\ displacement\end{matrix}} + {\underbrace{\frac{{v}_{ac} {C}_{f}}{{C}_{160} + {C}_{65} + {C}_{67} + {C}_{68} + {C}_{if} + {C}_{+} + {C}_{f}}}}_{feedthrough component} \qquad Equation 9$$

In some embodiments, to calculate the displacement of the sensed arm of the DETF resonator forces on both actuation and sensed arms of the DETF are calculated by force energy method illustrated in the following equations 10 and 11, respectively:

$${F}_{a} = {\underbrace{\frac{2 ϵ {AV}_{DC}^{2} {x}_{1}}{{g}^{3}}}}_{\begin{matrix}spring softening \\ on actuation arm\end{matrix}} + {\underbrace{\frac{ϵ {AV}_{DC} {v}_{ac}}{{g}^{2}}}}_{actuates DETF} \qquad Equation 10$$

$${F}_{S} = {\underbrace{\frac{2 ϵ {AV}_{DC}^{2} {x}_{2}}{{g}^{3}}}}_{\begin{matrix}spring softening \\ on actuation arm\end{matrix}} - {\underbrace{\frac{ϵ {AV}_{DC} {v}_{6}}{{g}^{2}}}}_{\begin{matrix}affects motion \\ of sensing arm\end{matrix}} \qquad Equation 11$$

With respect to equations 9 and 10, Fₐ is electrostatic force acting on the actuation arm or the DETF and Fₛ is the electrostatic force acting on the sensed arm of the DETF. Further, the equation for x₂ from below equation 12 is substituted in the equation for v₆ derived above:

$${\tilde{X}}_{2} = \frac{1}{2} [ \frac{{C}_{160} \frac{{V}_{DC}}{g} {\tilde{V}}_{ac}}{{s}^{2} m + sc + k} ] [ 1 - \frac{{C}_{f}}{{C}_{total}} ] - \frac{1}{2} [ \frac{{C}_{160} \frac{{V}_{DC}}{g} {\tilde{V}}_{ac}}{{s}^{2} m + sc + ( k + 2 {k}_{c} )} ] [ 1 + \frac{{C}_{f}}{{C}_{total}} ] \qquad Equation 12$$

By substituting the equation for x₂, as described above, from equation 12 in the equation for v₆ derived above, expression for v₆ can be obtained as shown in equation 13 and equation 14, below:

$${\tilde{V}}_{6} = \frac{{C}_{f}}{{C}_{totalVA}} {\tilde{V}}_{ac} + \frac{{\tilde{V}}_{ac}}{2} [ \frac{{C}_{160}}{{C}_{totalVA}} \frac{{V}_{DC}}{g} ] [ ( \frac{{C}_{160} \frac{{V}_{DC}}{g}}{{s}^{2} m + sc + k} ) ( 1 - \frac{{C}_{f}}{{C}_{totalVA}} ) - ( \frac{{C}_{160} \frac{{V}_{DC}}{g}}{{s}^{2} m + sc + ( k + {k}_{c} )} ) ( 1 + \frac{{C}_{f}}{{C}_{totalVA}} ) ] \qquad Equation 13$$

$${\tilde{V}}_{out} = \frac{{A}_{CL} {C}_{f}}{{C}_{totalVA}} {\tilde{V}}_{ac} + \frac{{\tilde{V}}_{ac}}{2} [ \frac{{C}_{160}}{{C}_{totalVA}} \frac{{V}_{DC}}{g} ] [ ( \frac{{A}_{CL} {C}_{160} \frac{{V}_{DC}}{g}}{{s}^{2} m + sc + k} ) ( 1 - \frac{{C}_{f}}{{C}_{totalVA}} ) - ( \frac{{A}_{CL} {C}_{160} \frac{{V}_{DC}}{g}}{{s}^{2} m + sc + ( k + {k}_{c} )} ) ( 1 + \frac{{C}_{f}}{{C}_{totalVA}} ) ] \qquad Equation 14$$

With respect to equations 13 and 14, feedthrough capacitance, C_{f}, has been assumed/found/calculated to be constant for a given device for different measurement circuits/schemes/topologies. However, C_{totalVA} is affected by the circuit interfacing the device and the amplifier topology being used. Feedthrough signal can be reduced by having higher C_{totalVA}, through higher C_{if} and input capacitance of the amplifier. But this also reduces the transduced signal by the same extent. On the flip side, even with high interface capacitance (C_{if}) that includes stray line, routing and connector capacitances and high input capacitance of the amplifier (C₊), the extent of resonant signal that lies above the feedthrough level/the ratio of resonant signal to the feedthrough signal remains unchanged as long as the feedthrough signal is above intrinsic noise level of the circuit/measurement setup. Hence, for a given device where sensed and feedthrough capacitances, C₁₆₀ & C_{f} respectively, are fixed by the geometry of the fabricated device, it is advantageous to have a low value for C_{totalVA} to enable higher signal to noise ratio. As per some embodiments, since there is no direct means of measuring v₆, it can be calculated by dividing the measured voltage signal, vₒᵤₜ, by the closed loop gain, A_{CL}, of the amplifier, as presented in equation 15 below:

$${v}_{6} = \frac{{v}_{out}}{{A}_{CL}} \qquad Equation 15$$

In some embodiments, from a practical perspective, to set the DC potential of the sense electrode to zero, it is most convenient to set the potential of electrodes 5, 7 and 8 to 0V since electrode 8's potential greatly influences the potential of the electrically-floating sense electrode. Therefore, as per some of the embodiments, for the sake of simplicity, the electrodes 2, 4, 5, 7, and 8 are connected to the ground potential in subsequent discussion.

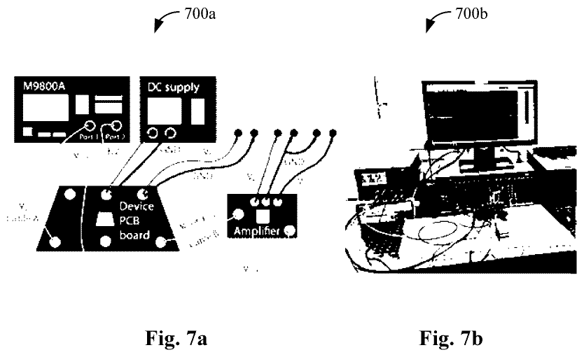

FIG. 7a illustrates a connection schematic 700a of resonance measurement system, and FIG. 7b illustrates an active measurement setup 700b that demonstrates the characterization of the first two in-plane resonance modes, in accordance with some embodiments of the present disclosure. In the experimental setup illustrated in the FIG. 7a-b, a DETF resonator fabricated using epi-seal process technology and measurement setup for the experiments done is shown. As an example, the S-parameter measurement is carried out using Keysight VNA M9800A. Port1 of the network analyser supplies AC signal to the actuation electrode of the resonator system via coaxial cable, cable-A. Coaxial cable, cable-B takes the output signal from sense electrode to the input of the amplifier. Amplifier output, Vₒᵤₜ, is fed to the port2 of the network analyzer and S21 data is recorded. As an example, Keysight low noise power source B2962A is used to supply bV_{DC} to electrodes 2, 4, 5, 7 and 8, and Keysight power supply E36312A is used to supply V_{DC} to the resonator and positive and negative bias supplies to the amplifier (VA or TIA).

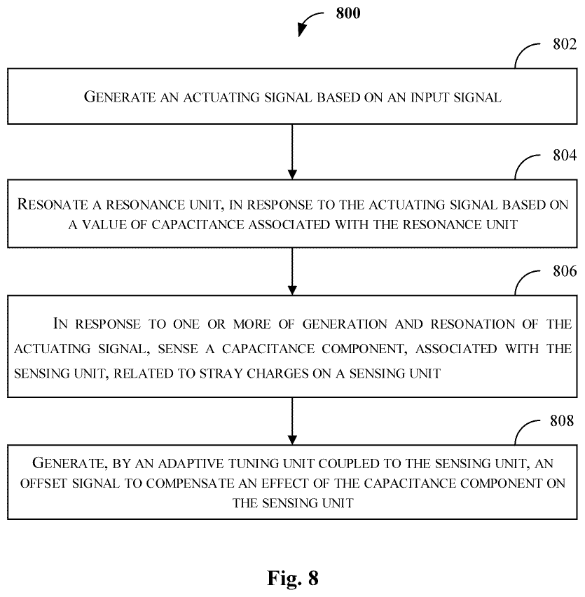

FIG. 8 illustrates a flowchart of a method for compensating for stray charges induced on an electrically floating electrode of Micro Electro-mechanical System (MEMS) devices or Nano Electro-mechanical System (NEMS) devices, in accordance with some embodiments of the present disclosure an aspect of the subject matter in accordance with one embodiment.

As illustrated in FIG. 8, the method 800 may comprise one or more steps. The method 800 may be described in the general context of computer executable instructions.

The order in which the method 800 is described is not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At step 802, an actuating unit may generate an actuating signal based on an input signal.

At step 804, a resonance unit, coupled to the actuating unit, may be resonated in response to the actuating signal, based on a value of capacitance associated with the resonance unit.

At step 806, in response to one or more of generation and resonation of the actuating signal, a sensing unit, capacitively coupled to the resonance unit, may sense a capacitance component, associated with the sensing unit, related to stray charges on the sensing unit.

At step 808, an adaptive tuning unit, coupled to the sensing unit, may generate an offset signal to compensate an effect of the capacitance component on the sensing unit. In an embodiment, the method 800 may further comprise generating a DC bias voltage. For example, the DC bias voltage may be transferred to the adaptive tuning unit. The sensing unit may be coupled to a Direct Current (DC) bias voltage generation unit. The adaptive tuning unit may be configured to generate the offset signal based on the DC bias voltage, to compensate the effect of the capacitance component on the sensing unit. In an embodiment, the method 800 may further comprise generating an Alternating Current (AC) bias voltage. For example, the AC bias voltage may be transferred to the adaptive tuning unit. The sensing unit may be coupled to an Alternating Current (AC) bias voltage generation unit. In an example, the adaptive tuning unit may be configured to generate the offset signal based on the AC bias voltage, to compensate the effect of the capacitance component on the sensing unit.

In an embodiment, the method 800 may further comprise amplifying, by a sensing amplifier coupled to the sensing unit, an output signal received from the sensing unit. In an example, a Low Pass Filter (LPF), coupled to the sensing amplifier, may attenuate high-frequency noise components above a predetermined cutoff frequency, from the amplified output signal received from the sensing amplifier. In an embodiment, a signal processing element, coupled to the LPF, may be process a filtered signal received from the LPF. In an example, the signal processing element may transfer the processed signal to the adaptive tuning unit. The offset signal may be generated based on the processed signal to compensate the effect of the capacitance component on the sensing unit.

In an embodiment, the method 800 may further comprise receiving, by the signal processing element, an input signal comprising the filtered signal, received from the LPF, and a reference voltage. Further, the method 800 comprises processing, by the signal processing element, the input signal. Furthermore, the method 800 comprises transferring, by the signal processing element, the processed input signal to the adaptive tuning unit. In an embodiment, the offset signal may be generated based on the processed input signal to compensate the effect of the capacitance component on the sensing unit.

In an embodiment, the method 800 may further comprise sensing, by the sensing unit, the resonation of the resonance unit. In an example, the capacitance component may be further related to resultant charges associated with the one or more of generation and resonation of the actuating signal. The capacitance component may be one of a parasitic capacitance, an intended capacitance, or a stray capacitance.

Advantages Associated with the Present Disclosure

The present disclosure illustrates advantages of the VA-based measurement topology. However, a person skilled in the art will appreciate the same reasoning and advantageous effects may be achieved using equivalent, similar, and/or analogous implementations in the field of invention. As per the present subject matter, there are certain advantages of using described VA measurement topology over standard TIA methodology. The present subject matter enables availability of the tuning/controlling/compensating knob bV_{DC}. As discussed in the above description in detail, a control/tuning/compensating knob bV_{DC} is introduced to provide desired robust DC biasing in presence of unknown/stray capacitances. Tuning/control/compensating voltage bV_{DC} is determined for each value of the resonator bias voltage V_{DC} by setting the AC voltage to zero by shorting the actuation electrode to the common ground terminal of the circuit. To demonstrate effect of tuning/control/compensating voltage on the DC voltage observed on the sense electrode, only electrodes 2, 4, 5, and 7 are connected to the voltage source bV_{DC}. The electrode 8 is terminated in the ground terminal instead of bV_{DC} since connecting this electrode to bV_{DC} greatly enhances the sensitivity of the induced voltage on the sense electrode due to the tuning/control/compensating voltage. However, such high sensitivity is not desirable as a tiny, sub-measurement resolution, change in tuning voltage may induce a large voltage change on/at the sense electrode. Further, as described in detail, a negative bV_{DC} has to be applied to preserve 0V dc potential on the sense electrode as V_{DC} is increased.

As discussed in the above description, performance and stability of a TIA is severely affected by the stray capacitance present at its inverting terminal, whereas performance of VA is not affected to the extent of compromising its stability even if same stray capacitance is present at its non-inverting terminal. To compare the two measurement setups/topologies, the extent of resonant signal may be plotted which lies above the feedthrough level, which is the ratio of resonant signal to the feedthrough signal, as the length of cable-B is varied by adding cables in series using standard SubMiniature version A (SMA) connectors. Therefore, same capacitance is added at the input of two amplifiers.

With respect to some examples, it is observed that the TIA-based setup starts showing performance deviation at 1 meter (m) cable length and becomes noisy due to amplifier instability for cables longer than 1 m. On the other hand, VA performs as good at 5 meters (m) cable length as it performs when only an SMA connector replaces cable-B. As per an example embodiment, 2 m, 3 m, 4 m, and 5 m cables are composed of different 1 m length cables which helps to introduce more capacitance via SMA connectors of each cable.

The non-inverting VA topology is immune to at least 5× more line capacitance than the TIA topology. Further, the noise performance is also 5× superior for non-inverting VA as compared to the TIA topology. Furthermore, based on the above description, it is illustrated that the non-inverting VA topology achieve a higher bandwidth than a TIA by a factor of 5. Though, the present disclosure describes in the context of the DETF device, a person skilled in the art will appreciate that the present subject matter may be applicable on implementation relating to other equivalent, similar, and/or analogous forms of capacitively transduced devices.

It will be understood by those within the art that, in general, terms used herein, and are generally intended as “open” terms (e.g., the term “including” should be interpreted as “including but not limited to,” the term “having” should be interpreted as “having at least,” the term “includes” should be interpreted as “includes but is not limited to,” etc.). For example, as an aid to understanding, the detailed description may contain usage of the introductory phrases “at least one” and “one or more” to introduce recitations. However, the use of such phrases should not be construed to imply that the introduction of a recitation by the indefinite articles “a” or “an” limits any particular part of description containing such introduced recitation to inventions containing only one such recitation, even when the introductory phrases “one or more” or “at least one” and indefinite articles such as “a” or “an” (e.g., “a” and/or “an” should typically be interpreted to mean “at least one” or “one or more”) are included in the recitations; the same holds true for the use of definite articles used to introduce such recitations. In addition, even if a specific part of the introduced description recitation is explicitly recited, those skilled in the art will recognize that such recitation should typically be interpreted to mean at least the recited number (e.g., the bare recitation of “two recitations,” without other modifiers, typically means at least two recitations, or two or more recitations).

The following provides an overview of aspects/examples of the present disclosure:

In some aspects, the present disclosure discloses a capacitively transduced Micro or Nano Electro-mechanical resonator system. The resonator system, as per the present subject matter, comprises an actuating unit, a resonance unit, a sensing unit, and an adaptive tuning unit. The actuating unit is configured to generate an actuating signal based on an input signal. The resonance unit is coupled to the actuating unit, and configured to resonate in response to the actuating signal based on a value of capacitance associated with the resonance unit. The sensing unit is capacitively coupled to the resonance unit. The sensing unit is configured to, in response to one or more of generation and resonation of the actuating signal, sense a capacitance component, associated with the sensing unit, related to stray charges on the sensing unit. The adaptive tuning unit is coupled to the sensing unit, to generate an offset signal to compensate an effect of the capacitance component on the sensing unit.

In further related aspects, the sensing unit is coupled to a Direct Current (DC) bias voltage generation unit configured to generate a DC bias voltage. The DC bias voltage is transferred to the adaptive tuning unit. The adaptive tuning unit is configured to generate, based on the DC bias voltage, the offset signal to compensate the effect of the capacitance component on the sensing unit.

In further related aspects, the sensing unit is coupled to an Alternating Current (AC) bias voltage generation unit configured to generate an AC bias voltage. The AC bias voltage is transferred to the adaptive tuning unit. The adaptive tuning unit is configured to generate, based on the AC bias voltage, the offset signal to compensate the effect of the capacitance component on the sensing unit.

In some related aspects, the resonator system further comprises a sensing amplifier, a Low Pass Filter (LPF), and a signal processing element. The sensing amplifier is coupled to the sensing unit, and configured to amplify an output signal received from the sensing unit. The LPF is coupled to the sensing amplifier, and configured to attenuate high-frequency noise components above a predetermined cutoff frequency, from the amplified output signal received from the sensing amplifier. The signal processing element is coupled to the LPF, and configured to process a filtered signal received from the LPF. The signal processing element is further configured to transfer the processed signal to the adaptive tuning unit. The adaptive tuning unit is configured to generate, based on the processed signal, the offset signal to compensate the effect of the capacitance component on the sensing unit.

In further related aspects, the signal processing element is configured to receive an input signal comprising the filtered signal, received from the LPF, and a reference voltage. Further, the signal processing element is configured to process the input signal and transfer the processed input signal to the adaptive tuning unit. The adaptive tuning unit is configured to generate, based on the processed input signal, the offset signal to compensate the effect of the capacitance component on the sensing unit.

In some aspects, to compensate an effect of the capacitance component on the sensing unit, the adaptive tuning unit is configured to independently control a Direct Current (DC) component associated with the sensing unit. Further, by independently controlling the DC component, the sensing unit is maintained at an electrically floating potential. The sensing amplifier is a differential amplifier. The adaptive tuning unit comprises a feed-through compensating unit.

In further related aspects, the sensing unit is further configured to sense the resonation of the resonance unit. The capacitance component is further related to resultant charges associated with the one or more of generation and resonation of the actuating signal. The capacitance component is one of a parasitic capacitance, an intended capacitance, or a stray capacitance.

In some aspects, the resonator system further comprises an enclosure enclosing at least one of the actuating unit, the resonance unit, the sensing unit, and the adaptive tuning unit.

In some aspects, the present disclosure discloses a method for implementation the method comprising generating, by an actuating unit, an actuating signal based on an input signal. Further, the method comprises resonating a resonance unit coupled to the actuating unit, in response to the actuating signal based on a value of capacitance associated with the resonance unit. The method further comprises in response to one or more of generation and resonation of the actuating signal, sensing, by a sensing unit capacitively coupled to the resonance unit, a capacitance component, associated with the sensing unit, related to stray charges on the sensing unit. Further, the method comprises generating, by an adaptive tuning unit coupled to the sensing unit, an offset signal to compensate an effect of the capacitance component on the sensing unit.

In further related aspects, the method further comprises generating a DC bias voltage, wherein the DC bias voltage is transferred to the adaptive tuning unit. The sensing unit is coupled to a Direct Current (DC) bias voltage generation unit. The adaptive tuning unit is configured to generate, based on the DC bias voltage, the offset signal to compensate the effect of the capacitance component on the sensing unit.

In further related aspects, the method further comprises generating an AC bias voltage. The AC bias voltage is transferred to the adaptive tuning unit. The sensing unit is coupled to an Alternating Current (AC) bias voltage generation unit. The adaptive tuning unit is configured to generate, based on the AC bias voltage, the offset signal to compensate the effect of the capacitance component on the sensing unit.

In further related aspects, the method further comprises amplifying, by a sensing amplifier coupled to the sensing unit, an output signal received from the sensing unit. Further, the method comprises attenuating, by a Low Pass Filter (LPF) coupled to the sensing amplifier, high-frequency noise components above a predetermined cutoff frequency, from the amplified output signal received from the sensing amplifier. Furthermore, the method comprises processing, by a signal processing element coupled to the LPF, a filtered signal received from the LPF. The method further comprises transferring, by the signal processing element, the processed signal to the adaptive tuning unit. The offset signal is generated based on the processed signal to compensate the effect of the capacitance component on the sensing unit.

In further related aspects, the method further comprises receiving, by the signal processing element, an input signal comprising the filtered signal, received from the LPF, and a reference voltage. Further, the method comprises processing, by the signal processing element, the input signal. The method further comprises transferring, by the signal processing element, the processed input signal to the adaptive tuning unit. The offset signal is generated based on the processed input signal to compensate the effect of the capacitance component on the sensing unit.

In further related aspects, the method further comprises sensing, by the sensing unit, the resonation of the resonance unit. The capacitance component is further related to resultant charges associated with the one or more of generation and resonation of the actuating signal. The capacitance component is one of a parasitic capacitance, an intended capacitance, or a stray capacitance.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the present detailed description.

We claim:

1. A capacitively transduced Micro or Nano Electro Mechanical Resonator system, comprising:
one or more actuating units configured to generate one or more actuating signals based on one or more input signals;
one or more resonance units coupled to the one or more actuating units, wherein each of the one or more of resonance units is configured to resonate in response to the one or more actuating signals based on a value of capacitance associated with each of the respective one or more of resonance units;
a sensing unit capacitively coupled to the one or more resonance units, the sensing unit configured to, in response to one or more of generation of the one or more actuating signals and resonation of the one or more of resonance units, sense one or more capacitance component, associated with the sensing unit; and
an adaptive tuning unit coupled to the sensing unit, the adaptive tuning unit configured to:
generate a tuning signal to tune, based on at least one of the one or more capacitance component and the resonation of the one or more of resonance units, respective resonant frequency of each of the one or more of resonance units; and
selectively generate, based on the tuning, one or more amplified output signals.

2. The resonator system of claim 1, wherein,
the sensing unit comprises one or more sensing electrodes,
the amplified output signal is associated with one of an amplified voltage signal and a phase shifted amplified signal, and
the capacitance component is one of a parasitic capacitance, an intended capacitance, or a stray capacitance.

3. The resonator system of claim 1, wherein, in response to one or more of generation of the one or more actuating signals and resonation of the one or more of resonance units, the sensing unit is configured to sense an output signal, wherein the output signal comprises summation of one or more of resonated signals from the one or more of resonance units.

4. The resonator system of claim 1, wherein the sensing unit is coupled to a Direct Current (DC) bias voltage generation unit configured to:
generate a DC bias voltage, wherein the DC bias voltage is transferred to the adaptive tuning unit,
wherein the adaptive tuning unit is configured to generate, based on the DC bias voltage, the tuning signal to tune the respective resonant frequency of each of the one or more of resonance units.

5. The resonator system of claim 1, wherein the sensing unit is coupled to an Alternating Current (AC) bias voltage generation unit configured to:
generate an AC bias voltage, wherein the AC bias voltage is transferred to the adaptive tuning unit,
wherein the adaptive tuning unit is configured to generate, based on the AC bias voltage, the tuning signal to tune the respective resonant frequency of each of the one or more of resonance units.

6. The resonator system of claim 1, further comprises:
a sensing amplifier coupled to the sensing unit, and configured to amplify an output signal received from the sensing unit, wherein the sensing amplifier is a differential amplifier;
a Low Pass Filter (LPF) coupled to the sensing amplifier, and configured to attenuate high-frequency noise components above a predetermined cutoff frequency, from the amplified output signal received from the sensing amplifier; and
a signal processing element coupled to the LPF, and configured to:
process a filtered signal received from the LPF; and
transfer the processed signal to the adaptive tuning unit,
wherein the adaptive tuning unit is configured to tune the respective resonant frequency of each of the one or more of resonance units.

7. The resonator system of claim 6, wherein the signal processing element is configured to:
receive one or more input signals comprising the filtered signal, received from the LPF, and a reference voltage;
process the one or more input signals; and
transfer the processed input signal to the adaptive tuning unit,
wherein the adaptive tuning unit is configured to generate, based on the processed input signal, the tuning signal to tune the respective resonant frequency of each of the one or more of resonance units.

8. The resonator system of claim 1, wherein, to tune the respective resonant frequency of each of the one or more of resonance units, the adaptive tuning unit is configured to:
apply a Direct Current (DC) bias voltage to one or more electromechanical elements of each of the one or more of resonance units to shift the phase of the one or more input signals; and
generate an output value by adding the one or more of phase shifted input signals.

9. The resonator system of claim 1, wherein one or more structural parameters of the resonator system are configured to be dynamically modified, and
the adaptive tuning unit is further configured to:
generate an output value by adding the one or more amplified output signals pertaining to the dynamically modified one or more structural parameters.

10. The resonator system of claim 1, wherein the one or more actuating units are configured to receive one or more of input signals, and wherein the adaptive tuning unit is configured to:
shift a phase of each of the one or more of input signals to a predetermined phase angle; and
generate an output value by adding the one or more of phase shifted input signals.

11. The resonator system of claim 10, wherein, to tune the respective resonant frequency of each of the one or more of resonance units, the adaptive tuning unit is configured to apply individual Direct Current (DC) bias voltage to one or more electromechanical elements of each of the one or more of resonance units to shift the phase of each of the one or more of phase shifted input signals.

12. The resonator system of claim 1, further comprises a phase shifting element comprising a low pass filter, configured to shift the phase of the detected and amplified signal by a value in a range of 45 to 135 degrees or −45 to −135 degrees.

13. The resonator system of claim 1, wherein the one or more input signals is an input voltage signal, and wherein, to tune the respective resonant frequency of each of the one or more of resonance units, the adaptive tuning unit is configured to apply a Direct Current (DC) bias voltage to one or more electromechanical elements of each of the one or more of resonance units to amplify a voltage component of the input voltage signal.

14. The resonator system of claim 1, wherein the one or more input signals is an input voltage signal, and wherein the one or more actuating units are configured to receive one or more of input voltage signals, and wherein the adaptive tuning unit is configured to:
amplify a voltage component of each of the one or more of input voltage signals to a predetermined voltage; and
generate an output value by adding the one or more of amplified input voltage signals.

15. The resonator system of claim 1, wherein the one or more input signals is an input voltage signal, and wherein, to tune the respective resonant frequency of each of the one or more of resonance units, the adaptive tuning unit is configured to apply individual Direct Current (DC) bias voltage to one or more electromechanical elements of each of the one or more of resonance units to amplify a voltage component of each of the one or more of input voltage signals.

16. The resonator system of claim 1, further comprises:
an enclosure enclosing at least one of the actuating unit, the resonance unit, the sensing unit, and the adaptive tuning unit.

17. A method comprising:
generating, by one or more actuating units, one or more actuating signals based on one or more input signals;
resonating each of one or more of resonance units coupled to the one or more actuating units, in response to the one or more actuating signals based on a value of capacitance associated with each of the one or more of resonance units;
sensing, by the sensing unit capacitively coupled to the one or more resonance units and in response to one or more of generation of the one or more actuating signals and resonation of the one or more of resonance units, one or more capacitance component, associated with the sensing unit;
generating, by an adaptive tuning unit coupled to the sensing unit, a tuning signal to tune, based on at least one of the one or more capacitance component and the resonation of the one or more of resonance units, respective resonant frequency of each of the one or more of resonance units; and
selectively generating, by the adaptive tuning unit coupled to the sensing unit, based on the tuning, one or more amplified output signals.

18. The method of claim 17, further comprising:
sensing, by the sensing unit and in response to one or more of generation of the one or more actuating signals and resonation of the one or more of resonance units, an output signal, wherein the output signal comprises summation of one or more of resonated signals from the one or more of resonance units.

19. The method of claim 17, wherein the sensing unit is coupled to a Direct Current (DC) bias voltage generation unit, the method further comprises:
generating, by the DC bias voltage generation unit, a DC bias voltage, wherein the DC bias voltage is transferred to the adaptive tuning unit,
wherein the adaptive tuning unit is configured to generate, based on the DC bias voltage, the tuning signal to tune the respective resonant frequency of each of the one or more of resonance units.

20. The method of claim 17, wherein the sensing unit is coupled to an Alternating Current (AC) bias voltage generation unit, the method further comprises:
generating, by the AC bias voltage generation unit, an AC bias voltage, wherein the AC bias voltage is transferred to the adaptive tuning unit,
wherein the adaptive tuning unit is configured to generate, based on the AC bias voltage, the tuning signal to tune the respective resonant frequency of each of the one or more of resonance units.

21. The method of claim 17, further comprising:
amplifying, by a sensing amplifier coupled to the sensing unit, an output signal received from the sensing unit;
attenuating, by a Low Pass Filter (LPF) coupled to the sensing amplifier, high-frequency noise components above a predetermined cutoff frequency, from the amplified output signal received from the sensing amplifier; and
processing, by a signal processing element coupled to the LPF, a filtered signal received from the LPF; and
transferring, by the signal processing element, the processed signal to the adaptive tuning unit,
wherein the adaptive tuning unit is configured to tune the respective resonant frequency of each of the one or more of resonance units.
